(19) United States
(12) Patent Application Publication
(10) Pub. No.: US 2007/0196574 A1
(43) Pub. Date: Aug. 23, 2007

(54) Method and device for coating of a component part

(76) Inventors: Thomas Berndt, Berlin (DE); Helge Reymann, Briarcliff Manor, NY (US)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/651,362

(22) Filed: Jan. 9, 2007

(30) Foreign Application Priority Data
Jan. 9, 2006 (EP) 06000340.7

(51) Int. Cl. C23C 16/00

(52) U.S. Cl. 427/248.1; 118/726; 118/730

(57) ABSTRACT

A method for coating of a component part is made available, in which an evaporating of a coating material from a material feeder at low ambient pressure is brought about. The component part which is to be coated is located sufficiently near to the material feeder in such a way that, as a result, a depositing of vaporized coating material on the surface of the component part is brought about. A rotation of the component part around a rotational axis takes place while it is located sufficiently near to the material feeder for the bringing about of the depositing of coating material. The rotational axis is pivoted from a standard position towards the material feeder before or during the coating.

### CROSS REFERENCE TO RELATED APPLICATIONS

This application claims priority of European application No. 06000340.7 EP filed Jan. 9, 2006, which is incorporated by reference herein in its entirety.

### FIELD OF INVENTION

The invention relates to a method for coating of a component part, in which an evaporating of a coating material from a material feeder at low ambient pressure is brought about, and the component part which is to be coated is located close to the material feeder in such a way that, as a result, a depositing of vaporized coating material on the surface of the component part is brought about. In addition, the invention under consideration relates to a device for implementation of such a method.

### BACKGROUND OF INVENTION

Turbine component parts, for example rotor blades and stator blades of turbines, are provided with thermal barrier ceramic coatings in order to increase their resistance to the temperatures which occur in a gas turbine plant. As thermal barrier coatings (TBC, thermal barrier coating), for example, zirconium oxide coatings (ZrO₂ coatings) come into use, which are at least partially stabilized by yttrium oxide (Y₂O₃).

The applying of thermal barrier coatings, which are based on zirconium oxide, on a turbine blade is described for example in U.S. Pat. No. 4,676,994. There, the coating is applied by means of physical vapor deposition (PVD). For this, a melt of the ceramic material is heated in a crucible in a vacuum chamber to a point where a rapid evaporating process takes place. Vaporized ceramic molecules are deposited on the surface of the component part which is to be coated. So that a uniform coating on the whole surface ensues, the component part is continuously rotated at a fixed angular speed during the coating. In this way, it is ensured that all circumferential areas of the component part face the crucible, with the melt, at regular intervals.

A device for coating of a component part by means of a so-called EBPVD process (EBPVD=electron beam physical vapor deposition) is described in WO 01/31080 A2. In such a method, the rapid evaporating process of the ceramic material is brought about by means of an electron beam directed onto the material. The device which is described in WO 01/31080 A2 comprises a coating chamber into which turbine blades can be introduced. Ingots of ceramic material are located in the chamber, the surface of which ingots is liquefied by means of the electron beam to a point where the ceramic material evaporates from the surface. During the evaporating, the turbine blades which are located close to the ingots execute a rotational movement and/or an oscillatory movement.

### SUMMARY OF INVENTION

In contrast to the aforesaid prior art, it is an object of the invention under consideration to make available a method and a device by which an advantageous coating of component parts, especially of turbine component parts, such as turbine blades, can be realized.

This object is achieved by a method for coating of a component part as claimed in the independent claims, or by a device for coating of a component part as claimed in further independent claims. The dependent claims contain advantageous developments of the invention.

In the method according to the invention for coating of a component part, an evaporating of a coating material from a material feeder at low ambient pressure takes place. The component part which is to be coated is located close to the material feeder in such a way that, as a result, a depositing of vaporized coating material on the surface of the component part is brought about. During the coating process, a rotation of the component part takes place around a rotational axis which is pivoted from a standard position towards the material feeder before or during the coating. The evaporating of the coating material can take place in the method according to the invention especially by heating of the material feeder by means of electron beam heating.

While in the prior art the direction of the rotational axis extends perpendicularly in relation to the principal evaporating direction of the material, in the method according to the invention it is pivoted in the direction of the material feeder. With component parts which have sections which are perpendicular or approximately perpendicular to each other, such as turbine blades with a blade airfoil and a blade platform which extends approximately perpendicularly to the blade airfoil, this makes it possible to provide the two surfaces which are perpendicular to each other with a uniform coating. In the prior art, the rotational axis, however, lies so that in the case of turbines blades the surface of the blade airfoil certainly lies favorably towards the principal evaporating direction, however the surface of the blade platform extends to a large extent parallel to this evaporating direction. In the prior art, it is difficult, therefore, to provide both blade platform and also blade airfoil with a uniform coating. By the method according to the invention, it is possible, however, to provide both the surface of the blade platform and also the surface of the blade airfoil with a uniform and basically equally thick coating since both the surface of the blade airfoil and also the surface of the blade platform can be brought at a favorable angle to the principal evaporating direction. The same is also valid for other surfaces which are to be coated, which are to a large extent perpendicular to each other.

Advantageously, the pivoting movement takes place during the coating so that each of the surfaces, which are to a large extent perpendicular to each other, can have a favorable angle to the principal evaporating direction over a defined period of time. It is especially advantageous, in this connection, if both a pivoting movement of the rotational axis towards the material feeder and also away from the material feeder takes place. In this way, for example stator blades of a turbine can be coated uniformly, which stator blades have on both ends of the blade airfoil blade platforms, the opposite lying surfaces of which extend basically perpendicularly to the surfaces of the blade airfoil. An especially uniform coating can be achieved in this case if the pivoting movement takes place in a periodic manner around the standard position which represents a middle position of the rotational axis.

An angle of up to 30° has been proved as a suitable angle by which the rotational axis can be pivoted towards the material feeder or pivoted away from the material feeder.

In a further advantageous development of the invention, moreover, an axial movement of the component part takes place during the coating along a direction which corresponds to the direction of the rotational axis in the standard position. This axial movement, which is known also as wobble movement, can contribute to the compensating of inhomogeneities in the cone of vaporized material which emanates from the evaporation supply.

The method according to the invention is especially suitable for coating of turbine component parts with thermal barrier ceramic coatings.

A device according to the invention for coating of a component part comprises a vacuum chamber, a material feeder with coating material, which is located in the vacuum chamber, for example in the form of a material block (so-called ingot), a heater for heating of the surface of the material feeder in such a way that coating material evaporates from the surface of the material feeder, and a holder for holding at least one component part which is to be coated. The holder enables a rotation of the component part around a rotational axis. It is designed in such a way that it also allows a pivoting of the rotational axis from a standard direction at least towards the material feeder. The device according to the invention is suitable especially for implementation of the method according to the invention and so offers the advantages which are mentioned with regard to the method.

It is especially advantageous if the holder is designed in such a way that it allows a pivoting of the rotational axis from the standard direction both towards the material feeder and also away from the material feeder. The possible pivoting angles between the standard direction and the rotational axis can lie especially in the region of between −30° and 3020 . Furthermore, the holder can be designed in such a way that it also enables an axial displacing of the component part along the rotational axis.

In an advantageous development of the device according to the invention, this comprises a control unit for control of the movement which is allowed by the holder during the coating process. By means of suitable control routines, therefore, the movement sequences of pivoting of the rotational axis and/or displacing of the component part along the rotational axis, with simultaneous rotation of the component part around the rotational axis, which are beneficial to the component part which is to be coated, can be realized.

For heating of the surface of the material feeder the device advantageously comprises an electron beam heater.

The device according to the invention can be especially designed in such a way that the holder is suitable for holding of a turbine component part, especially a turbine blade, and the material feeder contains a ceramic material as coating material. Designed in such a way, the device according to the invention is suitable for applying a ceramic thermal barrier coating on a turbine component part, such as a rotor blade or stator blade of a gas turbine plant.

In a method for coating of a component part, especially a turbine component part, such as a turbine blade, an evaporating of a coating material from a material feeder at low ambient pressure is brought about. The component part which is to be coated in this case is located close to the material feeder in such a way that, as a result, a depositing of vaporized coating material on the surface of the component part is brought about. Furthermore, a displacing of the material feeder relative to the component part takes place during the coating. As a result, the material feeder can be located especially favorably for the component part which is to be coated. The implementation of this method can be effected by means of a device for coating of a component part, which device is equipped with a vacuum chamber, a material feeder with coating material, which is located in the vacuum chamber, a heater for heating of the surface of the material feeder in such a way that coating material evaporates from the surface of the material feeder, and a holder for holding at least one component part which is to be coated. In this device, the material feeder is located with displaceable effect relative to the holder. The methods and the devices of the independent and dependent claims can be combined, as the case may be.

### BRIEF DESCRIPTION OF THE DRAWINGS

Further features, characteristics and advantages of the invention under consideration result from the subsequent description of exemplary embodiments with reference to the attached figures.

FIG. 1 exemplarily shows a gas turbine in a longitudinal partial section.

FIG. 2 shows in perspective view a rotor blade or stator blade of a turbo-machine.

FIG. 3 shows a combustion chamber of a gas turbine.

FIG. 4 shows in a much schematized view an EBPVD device in a sectioned side view.

FIG. 5a-5c show different pivoted positions of the component part holder of the device from FIG. 4.

FIG. 6 shows the possible directions of movement of a turbine blade during the coating in the device from FIG. 4.

### DETAILED DESCRIPTION OF INVENTION

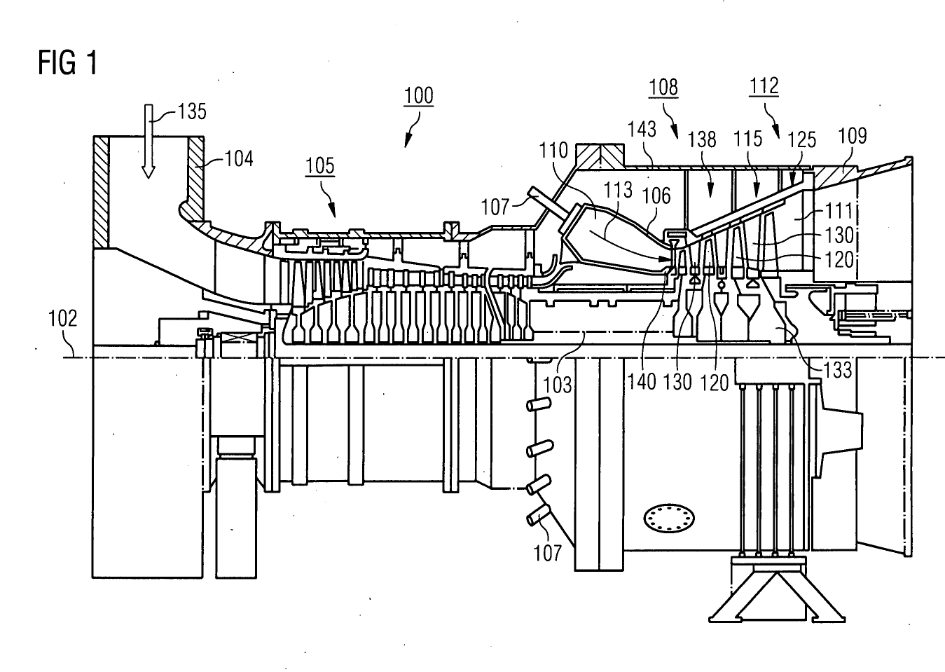

FIG. 1 exemplarily shows a gas turbine 100 in a longitudinal partial section. Inside, the gas turbine 100 has a rotor 103, also designated as a turbine rotor, which is rotatably mounted around a rotational axis 102. An intake duct 104, a compressor 105, a combustion chamber 110, for example a toroidal combustion chamber, especially an annular combustion chamber 106, with a plurality of coaxially disposed burners 107, a turbine 108 and the exhaust duct 109, are arranged in series along the rotor 103.

The annular combustion chamber 106 communicates with a hot gas passage 111, for example an annular hot gas passage. There, turbine stages 112, for example four turbine stages, which are connected one behind the other, form the turbine 108.

Each turbine stage 112 is formed from blade rings, for example two blade rings. Viewed in the flow direction of a working medium 113, a row 125 which is formed from rotor blades 120 follows a stator blade row 115 in the hot gas passage 111.

The stator blades 130 in this case are fastened on an inner casing 138 of a stator 143, whereas the rotor blades 120 of a row 125 are attached on the rotor 103, for example by means of a turbine disk 133.

A generator or driven machine (not shown) is coupled to the rotor 103.

During operation of the gas turbine 100, air 135 is inducted by the compressor 105 through the intake duct 104, and compressed. The compressed air which is made available at the end of the compressor 105 on the turbine side is guided to the burners 107 and mixed there with a fuel. The mixture is then combusted in the combustion chamber 110, forming the working medium 113. The working medium 113 flows from there along the hot gas passage 111 past the stator blades 130 and the rotor blades 120. On the rotor blades 120, the working medium 113 expands with impulse transmitting effect so that the rotor blades 120 drive the rotor 103, and the latter drives the driven machine which is coupled to it.

The component parts which are exposed to the hot working medium 113 are subjected to thermal stresses during operation of the gas turbine 100. The stator blades 130 and rotor blades 120 of the first turbine stage 112, viewed in the flow direction of the working medium 113, are thermally stressed most of all next to the heat shield blocks which line the annular combustion chamber 106.

In order to withstand the temperatures which prevail there, these can be cooled by means of a cooling medium.

Also, substrates of the component parts can have a directional structure, i.e. they are single-crystal (SX-structure) or have only longitudinally oriented grains (DS-structure).

As material for the component parts, especially for the turbine blades 120, 130 and component parts of the combustion chamber 110, for example iron-based, nickel-based or cobalt-based superalloys are used. Such superalloys are known, for example, from EP 1 204 776 B1, EP 1 306 454, EP 1 319 729 A1, WO 99/67435 or WO 00/44949; these documents are part of the disclosure.

Also, the blades 120, 130 can have coatings against corrosion (MCrAlX; M is at least one element of the iron (Fe), cobalt (Co), nickel (Ni) group, X is an active element and represents yttrium (Y) and/or silicon and/or at least one element of the rare earths or haffiium, as the case may be). Such alloys are known from EP 0 486 489 B1, EP 0 786 017 B1, EP 0 412 397 B1 or EP 1 306 454 A1, which are to be part of this disclosure.

A thermal barrier coating can still be provided on the MCrAlX, and for example consists of ZrO₂, Y₂O₃—ZrO₂, i.e. it is not partially or completely stabilized by yttrium oxide and/or by calcium oxide and/or by magnesium oxide.

By suitable coating methods, such as electron beam physical vapor deposition (EB-PVD), stalk-shaped grains are created in the thermal barrier coating.

The stator blade 130 has a stator blade root (not shown here) which faces the inner casing 138 of the turbine 108, and a stator blade end which lies opposite the stator blade root. The stator blade end faces the rotor 103 and is fixed on a fastening ring 140 of the stator 143.

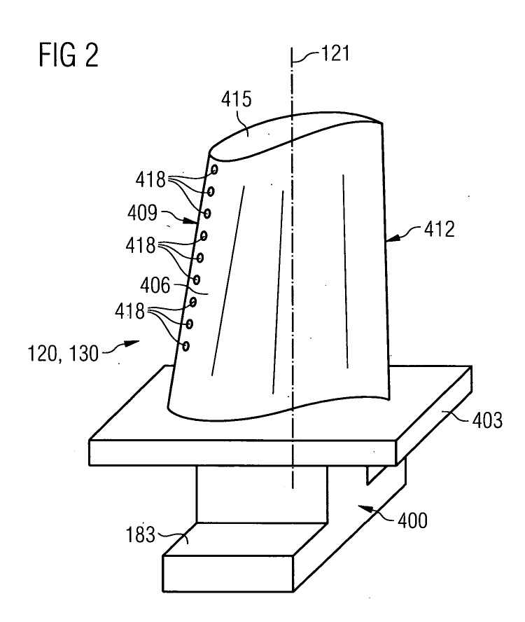

FIG. 2 shows in perspective view a rotor blade 120 or stator blade 130 of a turbo-machine, which extends along a longitudinal axis 121.

The turbo-machine can be a gas turbine of an aircraft or a gas turbine of a power generating plant for generating of electricity, a steam turbine, or a compressor.

The blade 120, 130 has a fastening section 400, a blade platform 403 which adjoins it, and also a blade airfoil 406, located one after the other along the longitudinal axis 121. As a stator blade 130, the blade 130 can have an additional platform (not shown) on its blade tip 415.

A blade root 183 is formed in the fastening section 400, which serves for fastening of the rotor blades 120, 130 on a shaft or on a disk (not shown).

The blade root 183, for example, is designed as an inverted T-root. Other developments as fir-tree roots or dovetail roots are possible.

The blade 120, 130 has a leading edge 409 and a trailing edge 412 for a medium which flows past the blade airfoil 406.

In conventional blades 120, 130, for example solid metal materials, especially superalloys, are used in all sections 400, 403, 406 of the blade 120, 130. Such superalloys are known, for example, from EP 1 204 776 B1, EP 1 306 454, EP 1 319 729 A1, WO 99/67435 or WO 00/44949; these documents are part of the disclosure. The blade 120, 130, in this case, can be produced by a casting process, also by means of directional solidification, by a forging process, by a milling process, or by a combination of these.

Workpieces with a single-crystal structure, or structures, are used as component parts for machines which, in operation, are exposed to high mechanical, thermal and/or chemical stresses. The manufacture of such single-crystal workpieces, for example, is carried out by directional solidification from the melt. This involves casting processes in which the liquid metallic alloy solidifies to form the single-crystal structure, i.e. the single-crystal workpiece, or solidifies directionally. In this case, dendritic crystals are oriented along the thermal flux and form either a stalk-like crystal grain structure (columnar, i.e. grains which extend over the whole length of the workpiece, and which here, in accordance with the language customarily used, are referred to as directionally solidified), or a single-crystal structure, i.e. the whole workpiece consists of one single crystal. In these processes, the transition to globulitic (polycrystal) solidification needs to be avoided since non-directional growth inevitably forms transverse and longitudinal grain boundaries which negate the favorable characteristics of the directionally solidified or single-crystal component part. Where the text refers in general terms to directionally solidified microstructures, this is to be understood as meaning both single crystals, which have no grain boundaries or at most have small-angle grain boundaries, and also stalk-like crystal structures, which no doubt have grain boundaries which extend in the longitudinal direction but have no transverse grain boundaries. In the context of the latter crystal structures, reference can also be made to directionally solidified microstructures (directionally solidified structures). Such processes are known from U.S. Pat. No. 6,024,792 and EP 0 892 090 A1; these documents are part of the disclosure.

The blades 120, 130 can also have coatings against corrosion or oxidation (MCrAlX; M is at least one element of the iron (Fe), cobalt (Co), nickel (Ni) group, X is an active element and represents yttrium (Y) and/or silicon and/or at least one element of the rare earths, or hafnium (Hf), as the case may be). Such alloys are known from EP 0 486489 B1, EP 0786017 B1, EP 0412397 B1, or EP 1 306454 A1, which are to be part of this disclosure.

A thermal barrier coating can still be provided on the MCrAlX, and for example consists of ZrO₂, Y₂O₃—ZrO₂, i.e. it is not partially or completely stabilized by yttrium oxide and/or by calcium oxide and/or by magnesium oxide. By suitable coating processes, such as electron beam physical vapor deposition (EB-PVD), stalk-shaped grains are created in the thermal barrier coating.

Refurbishment means that component parts 120, 130, after their use, if necessary need to be freed of protective coatings (for example, by sand-blasting). After that, a removal of the corrosion and/or oxidation layers, or products, as the case may be, is carried out. If necessary, cracks in the component part 120, 130 are repaired as well. Then, a recoating of the component part 120, 130 and a refitting of the component part 120, 130 is carried out.

The blade 120, 130 can be constructed hollow or solid. If the blade 120, 130 is to be cooled, it is hollow and, if necessary, still has film cooling holes 418 (shown by broken lines).

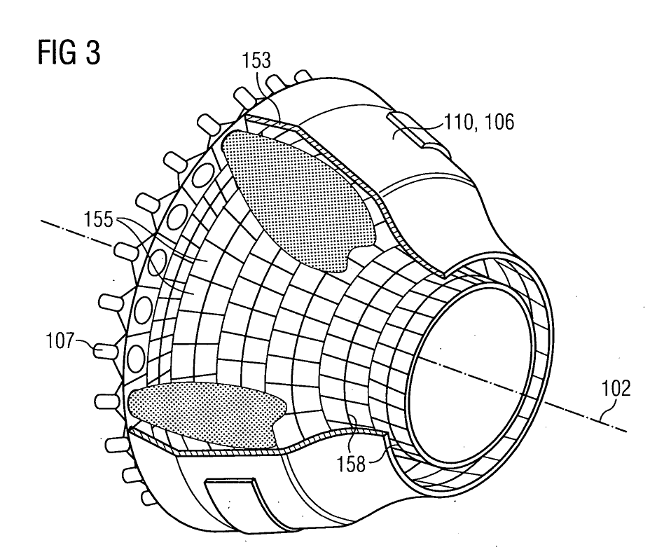

FIG. 3 shows a combustion chamber 110 of a gas turbine. The combustion chamber 110, for example, is designed as a so-called annular combustion chamber, in which a plurality of burners 107, which are arranged in the circumferential direction around the rotational axis 102, lead into a common combustion chamber space. For this purpose, the combustion chamber 110 in its entirety is designed as an annular construction which is positioned around the rotational axis 102.

To achieve a comparatively high efficiency, the combustion chamber 110 is designed for a comparatively high temperature of the working medium M of about 1000° C. to 1600° C. In order to enable a comparatively long period in service even at these operating parameters which are unfavorable for the materials, the combustion chamber wall 153, on its side facing the working medium M, is provided with an inner lining which is formed from heat shield elements 155.

Each heat shield element 155 is equipped on the working medium side with an especially heat resistant protective coating or is manufactured from high temperature resistant material. This can be solid ceramic blocks or alloys with MCrAlX and/or ceramic coatings. The materials of the combustion chamber wall and their coatings can be similar to the turbine blades.

On account of the high temperatures inside the combustion chamber 110, moreover, a cooling system can be provided for the heat shield elements 155 or for their mounting elements, as the case may be.

The combustion chamber 110 is designed especially for a detection of losses of the heat shield elements 155. For this purpose, a number of temperature sensors 158 are positioned between the combustion chamber wall 153 and the heat shield elements 155.

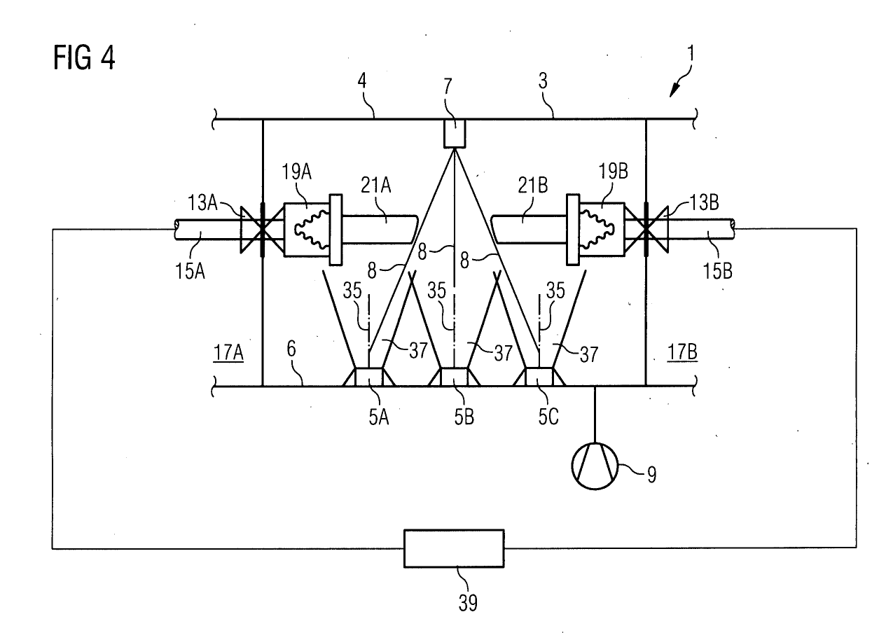

As an example for a device according to the invention for coating of a component part, FIG. 4 shows a system for implementation of an EBPVD process, in a much schematized presentation. The system and the coating process are subsequently described with reference to the coating of a gas turbine blade. It should be pointed out here, however, that the device and the method according to the invention can also be applied for coating of other component parts, especially other turbine component parts.

A ceramic thermal barrier coating is applied to the turbine blade, which coating in the exemplary embodiment under consideration is formed as a zirconium oxide coating (ZrO₂ coating), which is at least partially stabilized by yttrium (Y). However, other coatings, especially ceramic coatings, can also be applied on the component part which is to be coated.

The EBPVD device 1 which is shown in FIG. 4 comprises a vacuum chamber 3, three ingots 5a to 5c of coating material, which represent a material feeder for the coating material, at least one electron gun 7, which is located and formed in such a way that an electron beam can be directed onto the ingots 5a to 5c, and also a vacuum pump 9, by which the pressure in the vacuum chamber 3 can be reduced. During the coating, the vacuum chamber 3, by means of the vacuum pump 9, is evacuated to a low pressure, preferably to a pressure of not more than 1×10⁻⁵ bar (1 Pa). The temperature of the turbine blade is held at 900° C. to 1200° C. during the coating.

The electron gun 7 is located relative to the ingots 5a to 5c in such a way that its electron beam 8 can be directed unobstructed from the component parts 21a, 21b which are located in the vacuum chamber 3 onto the surfaces of the ingots 5a to 5c which face the inside of the chamber. For this purpose, the electron gun 7 can be installed on the cover 4 of the vacuum chamber 3, lying opposite the ingots 5a to 5c which are located on the bottom 6 of the vacuum chamber 3, as this is shown in FIG. 4. Alternatively, however, it is also possible to attach the electron gun 7 to one of the side walls of the vacuum chamber 3. It should be pointed out, moreover, that although an electron gun 7 is always spoken of in the singular, a plurality of electron guns 7 can also be provided, for example one electron gun 7 per ingot. If, as in the exemplary embodiment under consideration, only one electron gun 7 is provided, the electron beam 8 heats the surface of each one ingot 5a, 5b, 5c alternately. For this purpose, the electron gun 7 needs to be designed in such a way that the electron beam 8 can be directed onto all three ingots 5a, 5b, 5c in quick rotation.

The vacuum chamber 3, furthermore, comprises two operable shut-off components which lie opposite each other. These serve as closable openings through which manipulators 15a, 15b can be inserted from preparation chambers 17a, 17b into the vacuum chamber 3. The manipulators 15a, 15b are provided with holders 19a, 19b which are formed for the holding of component parts 21a, 21b which are to be coated, which in the exemplary embodiment under consideration, therefore, are formed for the holding of gas turbine blades. The preparation chambers 17a, 17b can be removed individually from the vacuum chamber 3 in order to exchange the turbine blades 21a, 21b. For this purpose, the manipulator 15a, 15b is withdrawn from the vacuum chamber 3 until it is located completely in the preparation chamber 17a or 17b, as the case may be. The valve 13a, 13b can then be closed so that the preparation chamber can be removed from the vacuum chamber 3 without the low pressure in the vacuum chamber 3 being negatively affected.

In a special variant of the EBPVD device 1, the ingots 5a to 5c are installed with displaceable effect along the bottom 6 of the chamber relative to the manipulators 19a, 19b, and, therefore, displaceable relative to the supported turbine blades 21a, 21b. They can then be displaced relative to the turbine blades during the coating process in order to take up a favorable position. The displacing of the ingots 5a to 5c can be carried out especially with oscillating effect, so can be carried out in a back and forth movement.

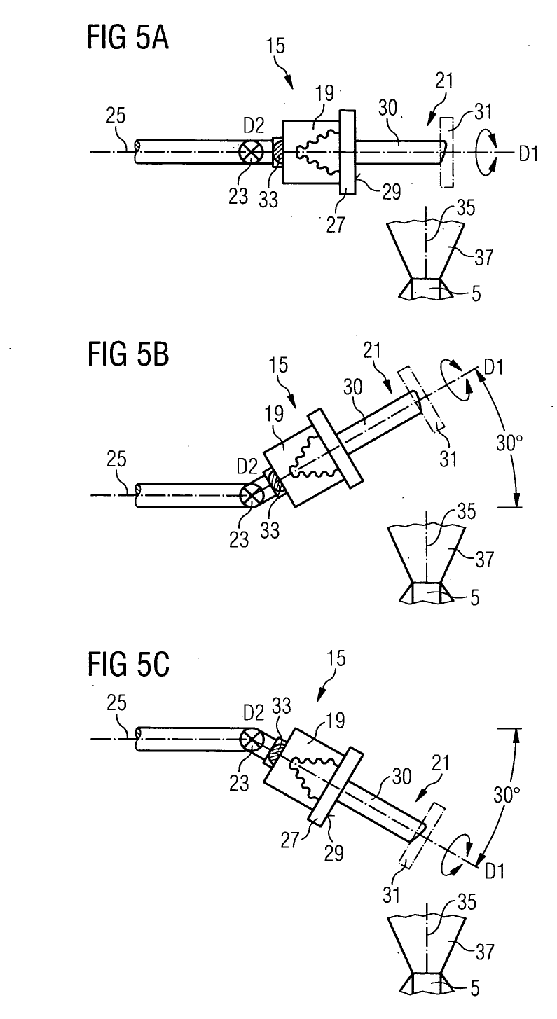

A manipulator 15 is shown enlarged in FIG. 5a to 5c. In addition to the holder 19, the manipulator 15 has a tilt axis 23 which extends perpendicularly to its central longitudinal axis 25. The holder 19, and, therefore, the supported turbine blade 15, can be pivoted around this tilt axis 23 relative to the longitudinal axis 25 by up to 30° to the ingots 5a to 5c, or pivoted away from the ingots 5a to 5c. The direction of the longitudinal axis 25 of the manipulator 15 represents a standard direction which defines the middle position of the holder 19. FIG. 5b and 5c show a pivoting of the holder 19 by 30° to this middle position away from (5b) or towards (5c) the ingots, as the case may be.

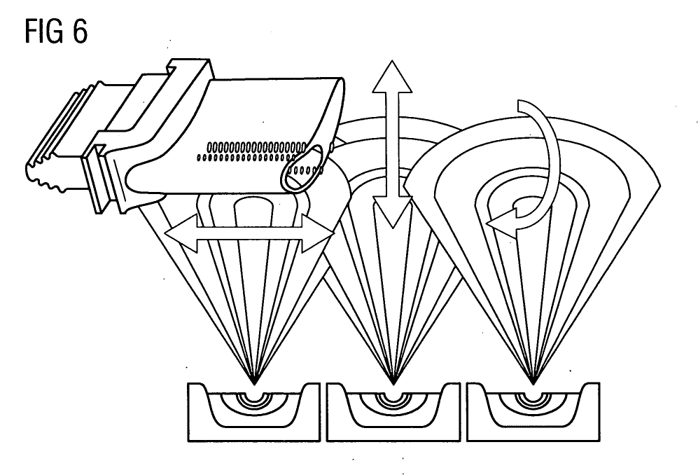

The holder 19 is also provided with a rotary joint 33, by means of which, together with the turbine blade 21 installed upon it, it can be rotated around the longitudinal axis 25 of the holder. Furthermore, the manipulator 15 can be displaced along the longitudinal axis 25 so that the movement capabilities which are shown in FIG. 6 are produced for a turbine blade 21 which is held in the holder 19.

The coating of a component part in the EBPVD device 1 which is shown is described below. For this, the manipulators 15a, 15b, with turbine blades 21a, 21b which are fastened in the holders 19a, 19b, are brought into the vacuum chamber 3 from the preparation chambers. By means of the electron gun 7, an electron beam heating of the surfaces of the ceramic ingots 5a to 5c which face the inside of the chamber is carried out so that the surfaces are fused and a rapid evaporating process starts.

The evaporating of the ceramic material occurs basically in a principal evaporating direction which corresponds approximately to the center line 35 of the vaporizing cone 37, which is shown in FIGS. 4 and 5. The vaporized ceramic material is absorbed on the surface of the turbine blade 21a, 21b and so leads to a ceramic coating. So that the turbine blade 21a, 21b is coated uniformly over the whole circumference, it rotates during the coating process around the longitudinal axis of the holder, which in FIG. 4 extends perpendicularly to the evaporating direction (compare also FIG. 5a) and which coincides with the longitudinal axis 25 of the manipulator 15. In this way, each surface section of the blade airfoil 30 faces the ingots 5 once during one period of rotation. As is also apparent, however, from FIG. 5a, the surface 29 of the blade platform 27 extends to a large extent perpendicularly to the principal evaporating direction 35 so that only a relatively small portion of material evaporates in the direction of this surface 29. Consequently, the absorption rate is relatively small. If now the longitudinal axis of the holder 19 is pivoted in the direction of the ingots 5, as is shown in FIG. 5c, then by this the absorption rate on the surface 29 of the blade platform 27 can be increased. The rotation of the turbine blade 21 around the longitudinal axis of the holder means that even regions of the blade platform 27 which lie in the shadows of the blade airfoil 30 during a part of the rotation directly face the ingots during another part of the rotation. In this way, a rapid and uniform coating of the blade platforms is also possible.

The position of the turbine blade 21 which is pivoted away from the ingots by up to 30°, which is shown in FIG. 5b, is especially relevant for such turbine blades which have blade platforms on both ends, as is the case with stator blades, for example. The arrangement of such a second blade platform 31 is shown by a broken line in FIGS. 5a to 5c. While the pivoted position (FIG. 5c) which faces the ingots 5 is advantageous for one blade platform, the pivoted position (FIG. 5b) which faces away from the ingots 5 is advantageous for the other blade platform. It is especially appropriate in this case to pivot the turbine blade periodically back and forth around the longitudinal axis 25 of the manipulator 15. As a result, the effect can be achieved of the two blade platforms being well coated uniformly. During the whole coating process, a back and forth movement of the blade 21 and/or of the ingots 5a to 5c, especially along the longitudinal axis 25 of the manipulator 15, can also take place. The combination of the movements which are shown in FIG. 6 enables an especially uniform coating of component parts.

1.-19. (canceled)

20. A method for coating of a component part, comprising:
evaporating coating material from a material feeder;
locating the component part sufficiently near to the material feeder to deposite vaporized coating material on the surface of the component part;
rotating the component part around a rotational axis while the component part is located sufficiently near to the material feeder for depositing the coating material;
pivoting the rotational axis from a standard position towards the material feeder; and
moving the component part axially during the coating in a direction which corresponds to the direction of the rotational axis in the standard position.

21. A method for coating of a component part, comprising:
evaporating coating material from a material feeder;
locating the component part sufficiently near to the material feeder to deposite vaporized coating material on the surface of the component part;
rotating the component part around a rotational axis while the component part is located sufficiently near the material feeder for depositing the coating material; and
pivoting the rotational axis from a standard position towards the material feeder not more than 30° relative to the standard position.

22. The method as claimed in claim 20, wherein the pivoting movement takes place during the coating process.

23. The method as claimed in claim 20, wherein the pivoting movement of the rotational axis takes place both towards the material feeder and away from the material feeder.

24. The method as claimed in claim 20, wherein the pivoting movement takes place in a periodic manner around the standard position which represents a middle position of the rotational axis.

25. The method as claimed in claim 20, wherein the pivoting of the rotational axis amounts to no more than 30° to the standard position.

26. The method as claimed in claim 20, wherein during the coating, an axial movement of the component part takes place in the direction which corresponds to the direction of the rotational axis in the standard position.

27. The method as claimed in claim 20, wherein the component part is a turbine component part, and the coating is a thermal barrier ceramic coating.

28. The method as claimed in claim 20, wherein a electron beam is provided to heat the material feeder for evaporating the coating material.

29. The method as claimed in claim 20, wherein the material feeder is displaced relative to the component part during the coating.

30. A device for coating of a component part, comprising:
a vacuum chamber;
a material feeder with coating material, the material feeder located in the vacuum chamber;
a heater for heating of the surface of the material feeder to evaporate coating material from the surface of the material feeder; and
a holder to hold at least one component part which is to be coated that allows:
a rotation of the component part around a rotational axis,
pivoting of the rotational axis from a standard direction at least towards the material feeder, and
pivoting angles between the standard direction and the rotational axis between −30° and 30°.

31. The device as claimed in claim 30, wherein the holder allows pivoting the rotational axis from the standard direction both towards the material feeder and away from the material feeder.

32. The device as claimed in claim 28, wherein the holder allows an axial displacing of the component part along that direction which corresponds to the direction of the rotational axis in the standard position.

33. The device as claimed in claim 30, wherein a control unit controls the movements which are allowed by the holder during the coating process.

34. The device as claimed in claim 30, wherein the heater is an electron beam heater.

35. The device as claimed in claim 30, wherein the holder is holding of a turbine component part, and the material feeder includes a ceramic material as coating material.

36. The device as claimed in claim 30, wherein the material feeder is displaceable relative to the holder.
